(19) United States
(12) Patent Application Publication
(10) Pub. No.: US 2014/0008761 A1
(43) Pub. Date: Jan. 9, 2014

(54) HIGH DENSITY CAPACITORS UTILIZING THIN FILM SEMICONDUCTOR LAYERS

(71) Applicant: YAN YE, Saratoga, CA (US)

(72) Inventor: YAN YE, Saratoga, CA (US)

(73) Assignee: Applied Materials, Inc., Santa Clara, CA (US)

(21) Appl. No.: 13/488,607

(22) Filed: Jun. 5, 2012

(51) Int. Cl. H01L 49/02

(52) U.S. Cl. CPC H01L 28/60
USPC 257/532

(57) ABSTRACT

The present invention generally relates to a capacitor. By utilizing a semiconductor material between two electrodes, the storage capacity of the capacitor is increased as compared to a metal-insulator-metal capacitor.

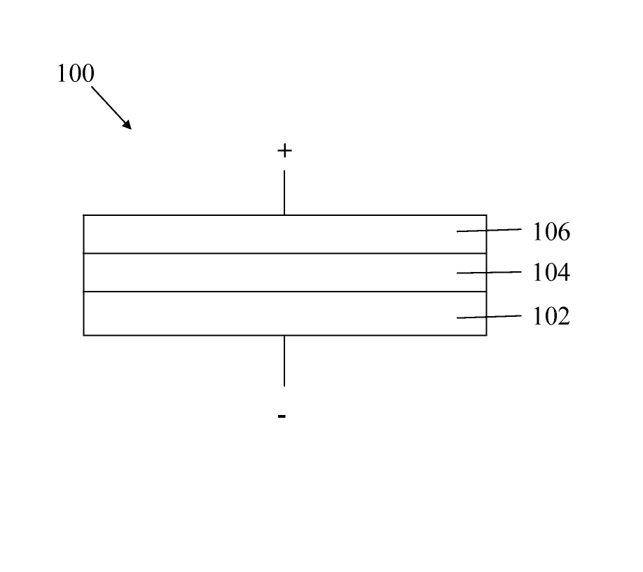

### GOVERNMENT RIGHTS IN THIS INVENTION

This Invention was made with Government support under Agreement No. DAAD19-02-3-0001 awarded by ARL. The Government has certain rights in this Invention.

### BACKGROUND OF THE INVENTION

1. Field of the Invention

Embodiments of the present invention generally relate to a capacitor.

2. Description of the Related Art

Conventional capacitors utilize a metal-insulator-metal structure whereby an insulating layer or material is sandwiched between two electrodes that function as a cathode and an anode. When there is a voltage across the electrodes, a static electric field develops across the insulating layer which causes a positive charge to collect on one of the electrodes while a negative charge collects on the other electrode. Energy is stored in the electrostatic field.

The amount of energy that can be stored in a capacitor is limited. Therefore, there is a need in the art for a capacitor with increased storage capacity.

### SUMMARY OF THE INVENTION

The present invention generally relates to a capacitor. By utilizing a semiconductor material between two electrodes, the storage capacity of the capacitor is increased as compared to a metal-insulator-metal capacitor. In one embodiment, a capacitor comprises a first electrode, a second electrode and a semiconductor layer coupled between the first electrode and the second electrode.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

The FIGURE shows a capacitor according to the invention.

### DETAILED DESCRIPTION

The present invention generally relates to a capacitor. By utilizing a semiconductor material between two electrodes, the storage capacity of the capacitor is increased as compared to a metal-insulator-metal capacitor.

The FIGURE shows a capacitor 100 according to the invention. The capacitor 100 includes a first electrode 102, a second electrode 106 and a semiconductor layer 104 sandwiched between the electrodes 102, 106. The semiconductor layer 104 may comprise a single layer or multiple layers.

The storage of the energy in the capacitor 100 is significantly enhanced by creations of polarizations at interfacial and in the bulk through thin film semiconductor layers 104 in the capacitor 100. If a single layer of semiconductor material is used as the semiconductor layer 104, non-symmetric charge trapping at different interfaces significantly enhances the storage capacity of the capacitor 100 by creation of polarizations in the bulk. The storage of the energy can be further enhanced by using electrodes with high porosity with thin film semiconductor coatings or composite materials.

The semiconductor layer 104 may comprise a combination of different materials such as amorphous silicon, ZnON, ZnO, metal oxides, metal oxynitrides or combinations thereof. If the semiconductor layer 104 comprises multiple layers, the different layers could be a combination of the same materials with different band gap, different work function, different Fermi-level, or different doping. For example, thin film ZnON layers may be deposited using different oxygen containing gases, different power levels, and different additive gases. Thus, when multiple layers are present for the semiconductor layer 104, at least one layer of the multiple layers comprises one or more of the following characteristics: different composition, different band gap, different work function, different Fermi-level, and different doping as compared to a second layer of the multiple layers. The electrodes 102, 106 may comprise a metal or a porous metal coated with semiconductor layers or a composite material of a metal and semiconductor.

A capacitor made with one or more semiconductor layers sandwiched between two electrodes has a higher energy storage capacitor as compared to a capacitor made with an insulating layer sandwiched between two electrodes. Additionally, a capacitor made from semiconductor materials could be used in many different electronic applications.

While the foregoing is directed to embodiments of the present invention, other and further embodiments of the invention may be devised without departing from the basic scope thereof, and the scope thereof is determined by the claims that follow.

1. A capacitor, comprising:
a first electrode;
a second electrode; and
a semiconductor layer coupled between the first electrode and the second electrode.

2. The capacitor of claim 1, wherein the semiconductor layer comprises amorphous silicon.

3. The capacitor of claim 2, wherein the first electrode comprises a porous metal.

4. The capacitor of claim 3, wherein the porous metal is coated with a semiconductor layer.

5. The capacitor of claim 4, wherein the second electrode comprises a porous metal.

6. The capacitor of claim 5, wherein the porous metal is coated with a semiconductor layer.

7. The capacitor of claim 1, wherein the semiconductor layer comprises a metal oxynitride.

8. The capacitor of claim 7, wherein the metal oxynitride comprises ZnON.

9. The capacitor of claim 8, wherein the first electrode comprises a porous metal.

10. The capacitor of claim 9, wherein the porous metal is coated with a semiconductor layer.

11. The capacitor of claim 10, wherein the second electrode comprises a porous metal.

12. The capacitor of claim 11, wherein the porous metal is coated with a semiconductor layer.

13. The capacitor of claim 1, wherein the semiconductor layer comprises a metal oxide.

14. The capacitor of claim 13, wherein the metal oxide comprises ZnO.

15. The capacitor of claim 14, wherein the first electrode comprises a porous metal.

16. The capacitor of claim 15, wherein the porous metal is coated with a semiconductor layer.

17. The capacitor of claim 16, wherein the second electrode comprises a porous metal.

18. The capacitor of claim 17, wherein the porous metal is coated with a semiconductor layer.

19. The capacitor of claim 1, wherein the semiconductor layer comprises multiple layers.

20. The capacitor of claim 19, wherein at least one layer of the multiple layers comprises one or more of the following characteristics: different composition, different band gap, different work function, different Fermi-level, and different doping as compared to a second layer of the multiple layers.
